(19) United States
(12) Patent Application Publication
(10) Pub. No.: US 2006/0139025 A1
(43) Pub. Date: Jun. 29, 2006

(54) Saturation-resistant magnetoresistive sensor for ferromagnetic screening

(75) Inventor: Frederick J. Jeffers, Escondido, CA (US)

Correspondence Address: GERALD W. SPINKS, P. O. BOX 5242, GLACIER, WA, 98244, US

(73) Assignee: MedNovus, Inc., Leucadia, CA (US)

(21) Appl. No.: 11/102,595

(22) Filed: Apr. 7, 2005

Related U.S. Application Data
(60) Provisional application No. 60/639,261, filed on Dec. 24, 2004.

(51) Int. Cl. G01B 7/30; H01L 43/08; H01L 43/02; H01L 43/00; G01B 7/14; H01L 43/10; G01R 33/06; H01L 43/04; H01L 43/06

(52) U.S. Cl. 324/207.21; 338/32 R

(57) ABSTRACT

An MRI pre-screening apparatus having an applied field source and a saturation-resistant magnetoresistive sensor, wherein the applied field source is sufficiently strong to magnetize any anticipated ferromagnetic threat object but the sensor is not saturated by the applied magnetic field. The sensor can be made saturation-resistant by being constructed of non-magnetic materials. A flux concentrator can be implemented to increase sensor sensitivity.

### CROSS REFERENCE TO RELATED APPLICATIONS

This application relies upon U.S. Provisional Pat. App. No. 60/639,261, filed on Dec. 24, 2004, titled “Nonsaturable Magnetoresistive Sensor for Ferromagnetic Screening”.

### STATEMENT REGARDING FEDERALLY SPONSORED RESEARCH OR DEVELOPMENT

Not Applicable

### BACKGROUND OF THE INVENTION

1. Field of the Invention

This invention is in the field of methods and apparatus used in pre-screening to prevent entry of ferromagnetic threat objects into the vicinity of a magnetic resonance imaging (MRI) magnet.

2. Background Art

Even small ferromagnetic objects that are inadvertently carried into a magnetic resonance imaging examination room can become potentially lethal projectiles in the very high field and high field gradient surrounding the MRI magnet. It is prudent to screen people for such objects to prevent possible accidents. Common metal detector portals, such as those used in airports, detect any metal. Hence they produce many false positive readings arising from coins, etc., which are non-magnetic, and, hence, present no danger in the MRI setting.

Existing ferromagnetic threat object screening portals often depend on the earth's magnetic field to magnetize the target objects. Many common small ferromagnetic objects, such as bobby pins and paper clips, are scarcely magnetized by the small earth's field, which has a magnitude of roughly 0.5 Oe. FIG. 1 shows the magnetic moment induced in a bobby pin, plotted versus a magnetic field applied parallel to the length of the pin. The bobby pin magnetization in the earth's 0.5 Oe field is only about 0.15% of the maximum, or saturation, value.

Some existing ferromagnetic portal detection systems apparently do detect small objects that have not been significantly pre-magnetized, but the systems are large and expensive. Detection of small objects is considerably facilitated if a moderate magnetic field of, say, 25 Oe is provided by magnetization means at the sides of the portal. Such an applied field induces a magnetic moment of about 30% in a bobby pin, for example. That applied field, therefore, increases the magnetic moment of the bobby pin by a factor of about 30 divided by 0.15, or 200 times, thus making its detection much more likely.

The sensors in the portal equipped with magnetization means still need to be very sensitive. However, nearly all highly sensitive magnetic field detectors have a very limited dynamic range, and this makes them unusable in this application. For example, in a 30-inch wide portal that is equipped with side magnets which provide 10 Oe to 25 Oe field in the center of the portal, the magnetic field near the sides is roughly 100 Oe. The sensors are immersed in this field, since they are located in the side structures of the portal.

FIG. 2 shows the transfer curve of a Honeywell #1022™ magnetoresistive field sensor, which is considered to be moderately sensitive. As can be seen, the sensor only functions properly in the linear region of its characteristic curve, which lies between about plus 10 Oe and minus 10 Oe. Hence, the sensor will not function at all when in a field of 100 Oe. Higher sensitivity sensors from Honeywell and other manufacturers have a correspondingly smaller dynamic range. Fluxgate sensors, and all other highly sensitive field sensors based on magnetic sensor materials, also suffer from this kind of problem.

### BRIEF SUMMARY OF THE INVENTION

It is desirable to have a ferromagnetic screening apparatus which is capable of detecting ferromagnetic threat objects by applying a sufficiently large field to magnetize the object in question, while the high sensitivity sensors employed remain in the effective portion of their dynamic range.

The present invention utilizes a currently available type of saturation-resistant magnetoresistive sensor in a screening apparatus having its own magnetic field source, to screen for ferromagnetic threat objects and thereby prevent the entry of such threat objects into the vicinity of a magnetic resonance imaging (MRI) apparatus. Use of saturation-resistant sensors allows the use of a relatively large applied field magnetic source, to apply to the threat object a field of approximately 25 Oe, or significantly higher, while the sensors remain in their effective sensing range, since the sensors are not saturated by the applied field source.

The novel features of this invention, as well as the invention itself, will be best understood from the attached drawings, taken along with the following description, in which similar reference characters refer to similar parts, and in which:

### BRIEF DESCRIPTION OF THE SEVERAL VIEWS OF THE DRAWINGS

FIG. 1 is a graph of the level of the initial magnetization of a bobby pin by magnetic fields of increasing strength;

FIG. 2 is a graph showing sensor output voltage versus field strength of a typical magnetoresistive sensor not suitable for the present invention;

FIG. 3 is a graph showing the transfer curve of a saturation-resistant magnetoresistor suitable for use in the present invention;

FIG. 4 is a perspective view of a saturation-resistant magnetoresistor suitable for use in the present invention;

FIG. 5 is a graph showing the transfer curve of a saturation-resistant magnetoresistive sensor equipped with a biasing permanent magnet;

FIG. 6 is a graph showing the sensitivity of the sensor addressed in FIG. 5, versus field strength;

FIG. 7 is a schematic section view of a pass-through or walk-through portal according to the present invention;

FIG. 8 is a schematic partial section view of a hand-held wand according to the present invention;

FIG. 9 is a schematic perspective view of a free-standing pillar according to the present invention;

FIG. 10 is a schematic partial section view of an eye screening, orbit screening, or brain screening instrument according to the present invention; and

FIG. 11 is a schematic section view of an embodiment of the present invention incorporating a flux concentrator.

### DETAILED DESCRIPTION OF THE INVENTION

There is at least one type of highly sensitive magnetic field detector that also has a very large dynamic range. This type of detector has been described by Siemens and referred to as a “Feldplatte Semiconductor Magnetoresistive Device”. These sensors are included in the type of sensors which will be referred to herein as saturation-resistant magnetoresistive sensors. Unlike other highly sensitive field detectors, they are made of nonmagnetic materials and, hence, they are unsaturated in all but extremely high magnetic field environments.

The saturation-resistant magnetoresistive sensor can be composed of a semi-conducting indium antimonide (InSb) matrix, in which are embedded oriented metallic conductive nickel antimonide (NiSb) needle-shaped inclusions. The needle-shaped inclusions are spaced some thousandths to some tenths of a millimeter apart. The highly conductive needle-shaped inclusions divert the current path when a magnetic field is applied perpendicular to the plane of the sensor, thus leading to a large increase in Ohmic resistance. Because of their high electrical conductivity, the needles eliminate the Hall Effect voltage, and cause a large change of resistance when the material is subjected to a magnetic field.

The present invention employs a saturation-resistant magnetoresistive sensor in pre-MRI screening for ferromagnetic threat objects. To accomplish this task, the saturation-resistant magnetoresistive sensors are incorporated into a pre-MRI screening portal, or a screening hand-held wand, or a free-standing screening pillar, or screening instruments for detecting retained ferromagnetic foreign bodies in the eye, the orbit, or the brain.

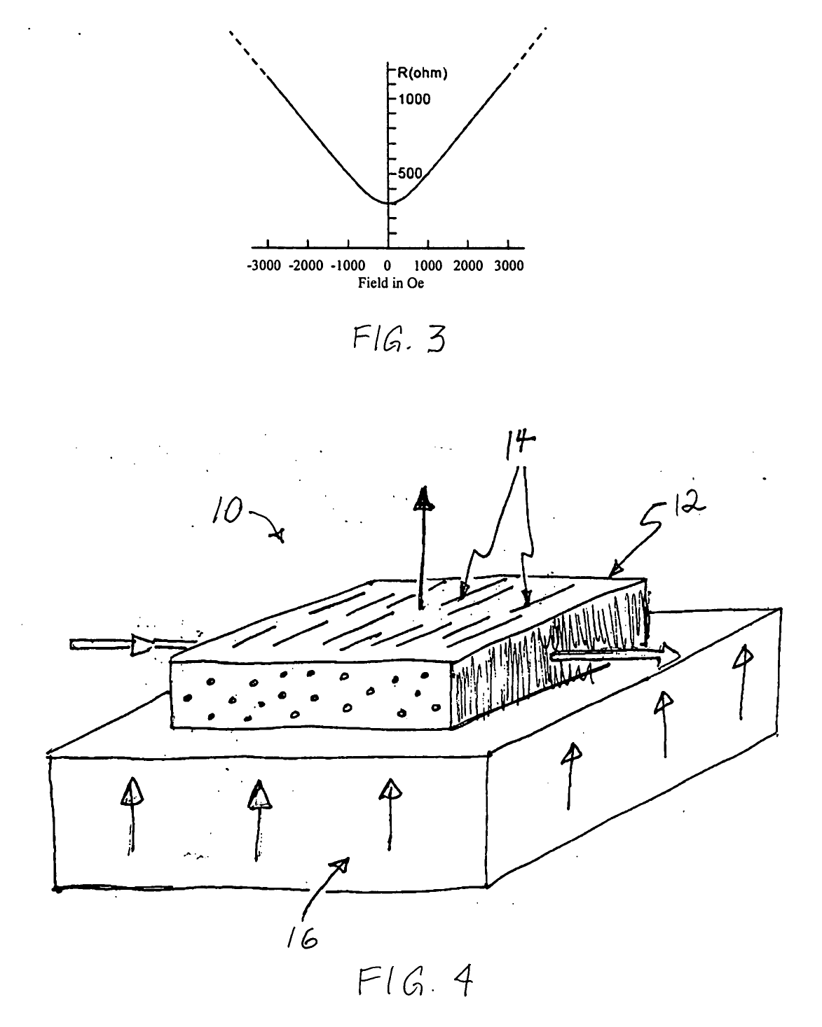

FIG. 3 is the transfer curve, showing sensor resistance vs. field strength, of such a saturation-resistant magnetoresistor. This figure shows that the sensor does not even saturate in a very large 3000 Oe field. The saturation-resistant magnetoresistive sensor transfer curve is symmetric about zero field. In order to use the sensor in its linear operating range, it must be equipped with an appropriate magnetic bias field. Hence, it must be “biased” by a permanent magnet to move the operating point up into the linear range. The sensor employs an internally mounted permanent magnet for this purpose.

FIG. 4 shows a saturation-resistant magnetoresistive sensor 10, with a magnetoresistor 12, in which are embedded a plurality of oriented metallic conductive nickel antimonide (NiSb) needle-shaped inclusions 14, and a biasing magnet 16. This type of saturation-resistant sensor can be used in the present invention.

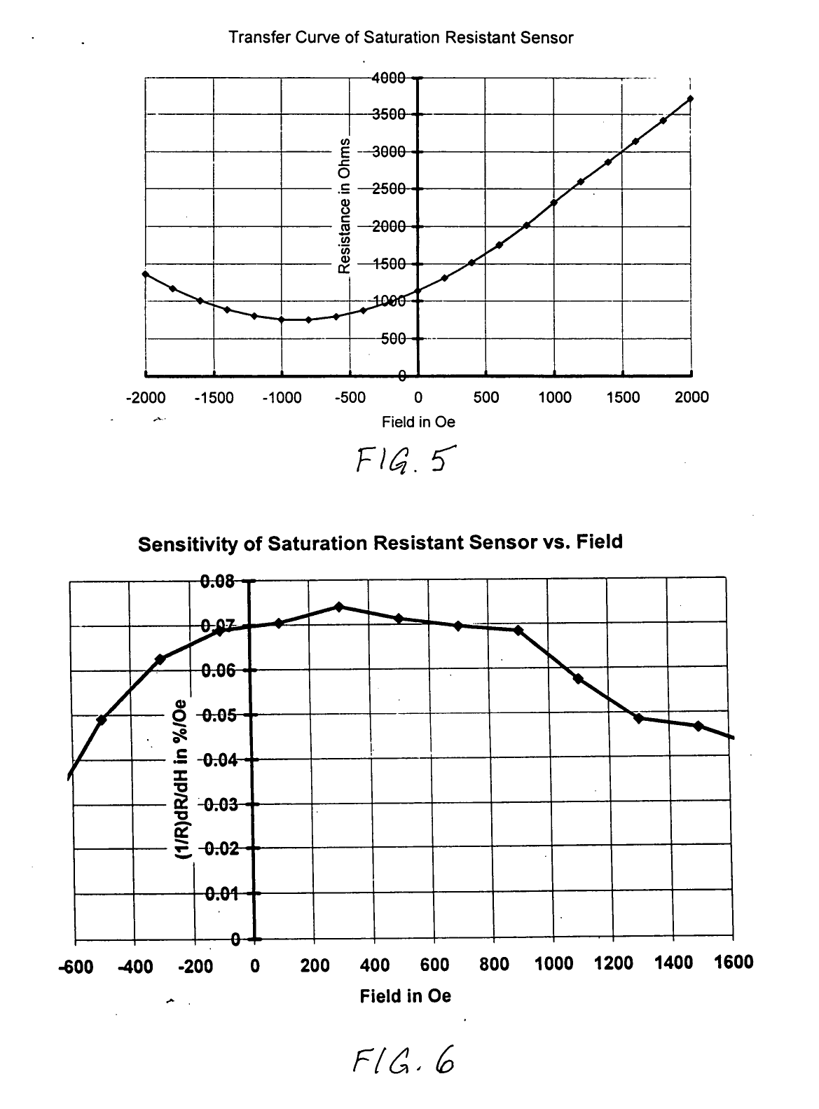

FIG. 5 shows the transfer curve of a saturation-resistant sensor as shown in FIG. 4, equipped with a biasing permanent magnet. The permanent magnet provides an internal bias field of about minus 800 Oe.

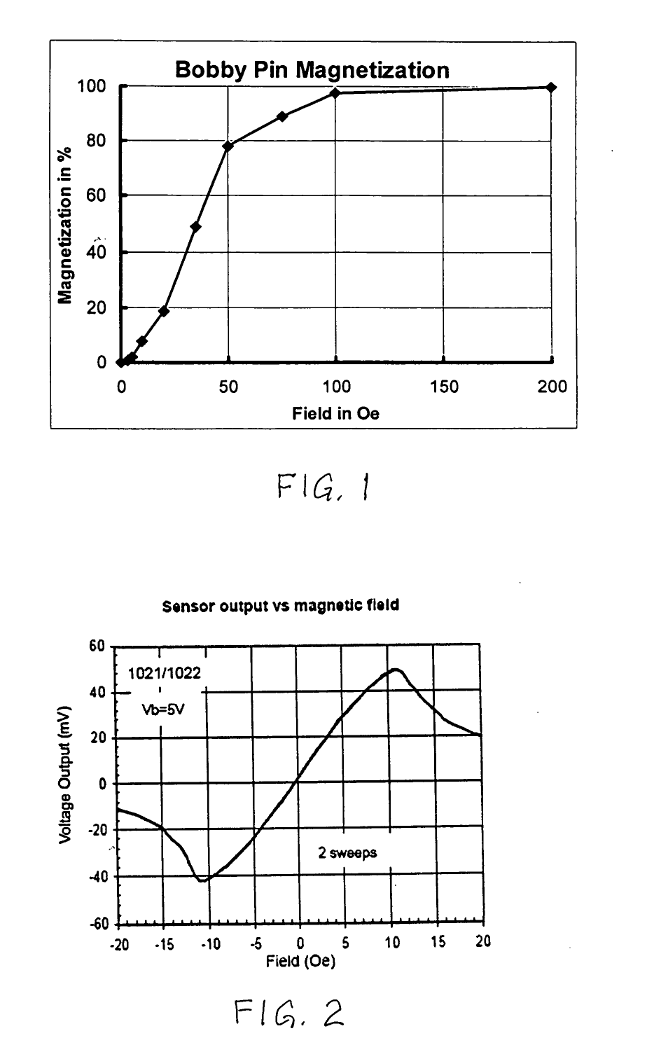

FIG. 6 shows a plot of the sensitivity of the sensor versus the strength of the applied field, which was derived from FIG. 5. As shown in FIG. 6, the sensitivity is scarcely affected by stray fields as large as minus 200 Oe to plus 900 Oe. Thus, the dynamic range of this sensor is about a factor of 50 greater than that of the sensor of FIG. 2, while the sensitivity is almost as high. The biasing magnet 16 in the sensor 10 of FIG. 4 could have been a good deal stronger to move the operating point out to the peak sensitivity field of about +350 Oe. This fact is used to advantage in the design of the detection systems of the present invention by orienting the sensors to provide part, or all, of this additional positive field. Thus, this sensor, in combination with an independently applied magnetic field to induce magnetization in ferromagnetic threat objects, is ideal for ferromagnetic detectors which are used for magnetic resonance imaging pre-screening.

The present invention includes the use of a saturation-resistant magnetoresistive sensor system for a screening pass-through or walk-through portal, for a hand-held screening wand, for a free-standing screening pillar, or for screening instruments for detecting retained ferromagnetic foreign bodies in the eye, in the orbit, or in the brain, all having applied field magnetizing sources provided to magnetize the target objects. The applied field to which a ferromagnetic threat object is subjected is preferably approximately 10 to 25 Oe for the portal, or for the free-standing pillar at its optimal working distance, or approximately 50 to 100 Oe for the eye screening, orbit screening, or brain screening instruments. The applied field to which a ferromagnetic object is subjected for the wand is a function of the distance between the instrument and the surface of the person being screened, but, at one inch from the person's skin, it is typically 100 Oe to 150 Oe. At the skin's surface, the applied field is 250 Oe to 300 Oe. The applied field sources preferably are permanent magnets, but current carrying electromagnetic coils can also be used. In the preferred embodiment, the sensors are configured in matching pairs as a gradiometer, to minimize extraneous interference from unwanted noise sources, such as the earth's magnetic field in the case of the hand-held wand.

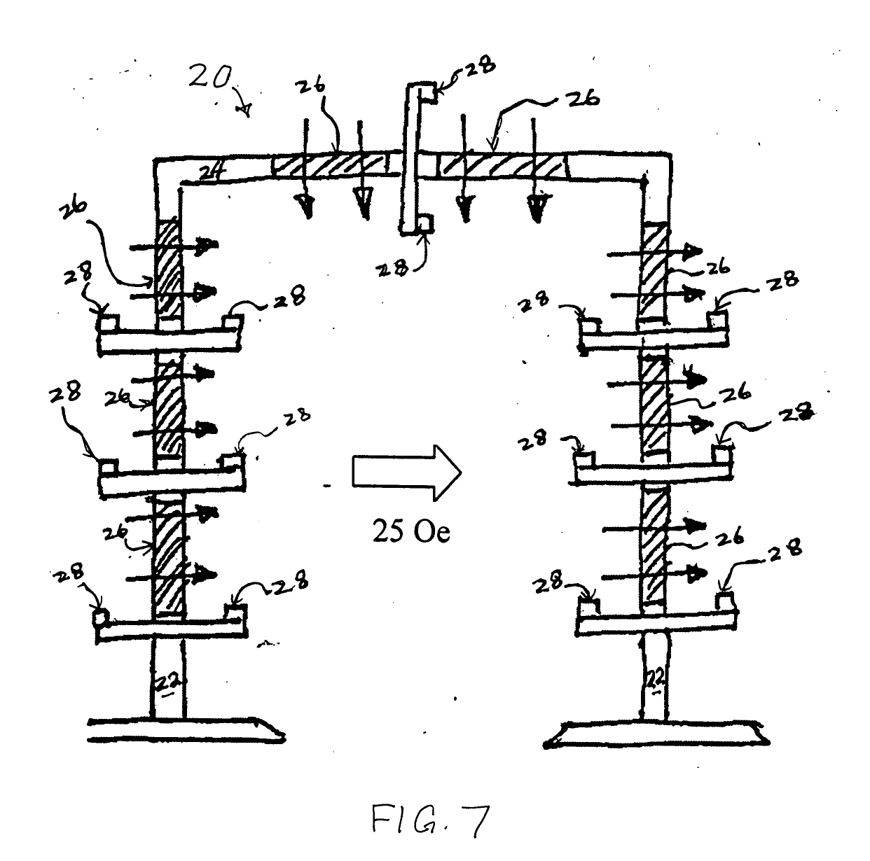

As shown in FIG. 7, a pass-through or walk-through portal 20 incorporating the present invention has side structures 22 and a connecting top structure 24. A plurality of permanent magnets 26 are mounted on each side structure 22. These magnets are sized and arranged to produce an applied field of approximately 10 Oe to 25 Oe in the center of the portal 20. Although only one sensor may be utilized in one embodiment of the invention, preferably, a plurality of sensor groups, such as one or more pairs of magnetoresistive sensors 28, configured as gradiometers, are also mounted on the side structures 22. Additional magnets 26 and sensors 28 can also be mounted on the top structure 24. The sensors 28 can be constructed of non-magnetic materials, such as InSb and NiSb, to make them saturation-resistant. Therefore, even though the sensors 28 are positioned in a magnetic field of approximately 100 Oe, as well as in the internal biasing field incorporated into the sensor itself, the sensors are not saturated, and they remain sensitive to the presence of any anticipated ferromagnetic threat object.

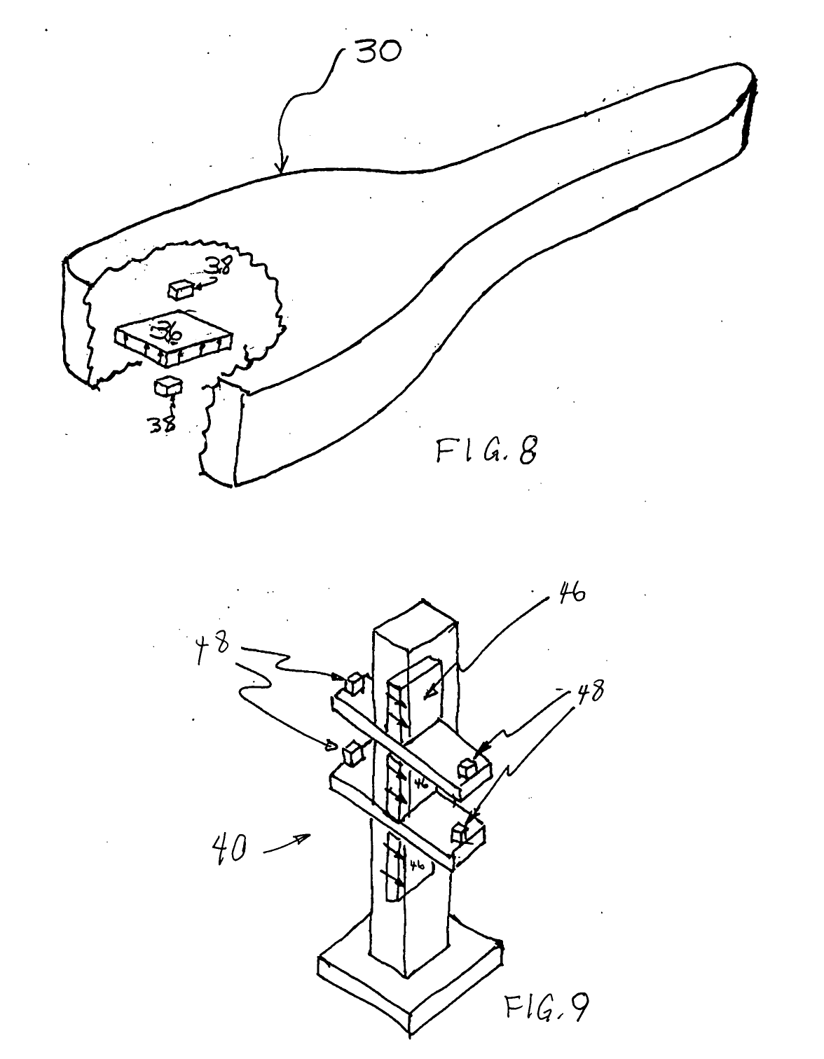

As shown in FIG. 8, a hand-held wand 30 can incorporate the present invention. A strong permanent magnet 36 is mounted on the wand 30. This magnet is sized and arranged to produce an applied field of approximately 100 to 150 Oe at a distance from the wand 30 that constitutes a typical spacing from the body of a subject being screened, such as one inch. This applied magnetic field reaches a significantly higher field of approximately 250 to 300 Oe, however, if the wand is rubbed directly on the patient's surface. A sensor group, such as a pair of magnetoresistive sensors 38, configured as a gradiometer, is also mounted on the wand 30. The sensors 38 are constructed of non-magnetic materials, such as InSb and NiSb, to make them saturation-resistant. Therefore, even though the sensors 38 are positioned in an independently-applied magnetic field of approximately 600 Oe, as well as in the internal biasing field incorporated into the sensor itself, the sensors are not saturated, and they remain sensitive to the presence of any anticipated ferromagnetic threat object.

As shown in FIG. 9, a free-standing pillar 40 can incorporate the present invention. A plurality of permanent magnets 46 are mounted on the pillar 40. These magnets are sized and arranged to produce an applied field of approximately 10 to 25 Oe at a distance from the pillar 40 that constitutes a typical spacing from the body of a subject being screened. Although the invention may employ only one sensor, preferably, one or more sensor groups, such as one or more pairs of magnetoresistive sensors 48, each group being configured as a gradiometer, are also mounted on the pillar 40. The sensors 48 can be constructed of non-magnetic materials, such as InSb and NiSb, to make them saturation-resistant. Therefore, even though the sensors 48 are positioned in a magnetic field of approximately 100 Oe, as well as in the internal biasing field incorporated into the sensor itself, the sensors are not saturated, and they remain sensitive to the presence of any anticipated ferromagnetic threat object.

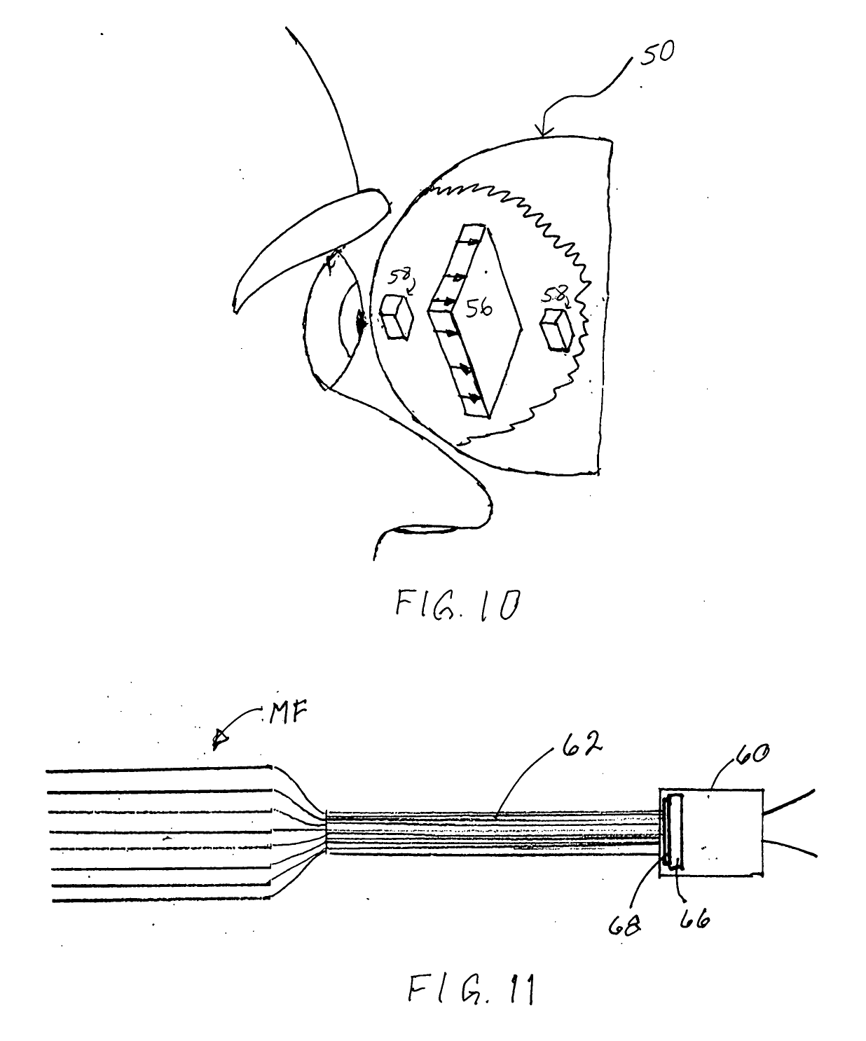

As shown in FIG. 10, an eye screening, orbit screening, or brain screening instrument 50 can incorporate the present invention. A permanent magnet 56 is mounted on the eye screening, orbit screening, or brain screening instrument 50. This magnet is sized and arranged to produce an applied field of approximately 50 to 100 Oe at a distance from the eye screening, orbit screening, or brain screening instrument 50 that constitutes a typical spacing from the body of a subject being screened. Configured as a gradiometer, a sensor group, such as a pair of saturation-resistant magnetoresistive sensors 58, is also mounted on the eye screening, orbit screening, or brain screening instrument 50. The sensors 58 can be constructed of non-magnetic materials, such as InSb and NiSb, to make them saturation-resistant. Therefore, even though the sensors 58 are positioned in an independently-applied magnetic field of approximately 600 Oe, as well as in the sensor's internal biasing field, the sensors are not saturated, and they remain sensitive to the presence of any anticipated ferromagnetic threat object.

In FIGS. 7, 8, 9, and 10, each sensor group is preferably composed of two or more matched sensors 28, 38, 48, 58, with each sensor group being arranged in a gradiometer configuration and wired in a Wheatstone bridge. This arrangement is used to eliminate spurious sensor signals resulting from distant sources of no interest to the detection apparatus. For example, when the wand is moved, the signals arising from the changes in the earth's field component parallel to the sensitive axis of the detectors are cancelled in this fashion.

As shown in FIG. 11, the use of a flux concentrator 62 can greatly increase the sensitivity, by a factor of four. The flux concentrator 62 is preferably a ferrite rod having a length to diameter ratio of 5 or more, and it is preferably placed in contact with a surface of the sensor assembly 60 as close as possible to the sensor 68. An internal bias magnet 66 can also be provided in the sensor assembly 60. As can be seen, the flux concentrator 62 concentrates the magnetic field MF emanating from the induced magnetization of a ferromagnetic threat object. An additional benefit of the flux concentrator of the present invention is to increase the field of the internal magnet 66 by about 500 Oe. This moves the zero field point out closer to the center of the maximum sensitivity range of −200 Oe to +900 Oe shown in FIG. 6. The effective dynamic range is thus increased significantly. Even with the factor-of-four increased sensitivity, the dynamic range of the sensor with the flux concentrator 62 is still over 125 Oe. Hence the magnetic field from the magnets used in the portal, pillar, wand, or other instrument does not degrade the sensitivity of the sensor.

While the particular invention as herein shown and disclosed in detail is fully capable of obtaining the objects and providing the advantages hereinbefore stated, it is to be understood that this disclosure is merely illustrative of the presently preferred embodiments of the invention and that no limitations are intended other than as described in the appended claims.

I claim:

1. An apparatus for screening for the presence of a ferromagnetic threat object, comprising:
a frame;
at least one applied field magnetic source mounted on said frame, said applied field source being adapted to produce a magnetic field of sufficient strength to provide detectable magnetization of a ferromagnetic threat object;
at least one saturation-resistant magnetoresistive sensor mounted on said frame, said sensor being adapted to maintain sufficient sensitivity to detect the presence of a ferromagnetic threat object while said sensor is subjected to said applied field.

2. The apparatus recited in claim 1, wherein said at least one saturation-resistant magnetoresistive sensor is constructed of non-magnetic materials.

3. The apparatus recited in claim 2, wherein said at least one saturation-resistant magnetoresistive sensor comprises an InSb-NiSb semiconductor sensor.

4. The apparatus recited in claim 1, wherein said at least one saturation-resistant magnetoresistive sensor is arranged in a gradiometer configuration.

5. The apparatus recited in claim 1, further comprising a flux concentrator positioned to concentrate magnetic flux sensed by said saturation-resistant magnetoresistive sensor.

6. The apparatus recited in claim 1, wherein said frame comprises a portal structure.

7. The apparatus recited in claim 6, wherein said at least one applied field source is adapted to produce a field of between approximately 10 Oe and approximately 25 Oe in the expected vicinity of a ferromagnetic threat object.

8. The apparatus recited in claim 1, wherein said frame comprises a hand-held wand.

9. The apparatus recited in claim 8, wherein said at least one applied field source is adapted to produce a field of between approximately 100 and approximately 150 Oe in the expected vicinity of a ferromagnetic threat object.

10. The apparatus recited in claim 8, wherein said at least one applied field source is adapted to produce a field of between approximately 250 and approximately 300 Oe in the expected vicinity of a ferromagnetic threat object.

11. The apparatus recited in claim 1, wherein said frame comprises a free-standing pillar.

12. The apparatus recited in claim 1 1, wherein said at least one applied field source is adapted to produce a field of between approximately 10 Oe and approximately 25 Oe in the expected vicinity of a ferromagnetic threat object.

13. The apparatus recited in claim 1, wherein said frame comprises a screening instrument for the eye.

14. The apparatus recited in claim 13, wherein said at least one applied field source is adapted to produce a field of between approximately 50 and approximately 100 Oe in the expected vicinity of a ferromagnetic threat object.

15. The apparatus recited in claim 1, wherein said frame comprises a screening instrument for the orbit.

16. The apparatus recited in claim 15, wherein said at least one applied field source is adapted to produce a field of between approximately 50 and approximately 100 Oe in the expected vicinity of a ferromagnetic threat object.

17. The apparatus recited in claim 1, wherein said frame comprises a screening instrument for the brain.

18. The apparatus recited in claim 17, wherein said at least one applied field source is adapted to produce a field of between approximately 50 and approximately 100 Oe in the expected vicinity of a ferromagnetic threat object.

19. The apparatus recited in claim 1, wherein said at least one applied field source is a permanent magnet.

20. The apparatus recited in claim 1, wherein said at least one applied field source is an electromagnetic coil.

21. The apparatus recited in claim 1, wherein said at least one saturation-resistant magnetoresistive sensor comprises a magnetoresistor and a biasing permanent magnet.

22. The apparatus recited in claim 21, wherein said biasing permanent magnet produces a field of approximately 800 Oe.

23. A method for screening for the presence of a ferromagnetic threat object, comprising:
providing an applied field magnetic source and a saturation-resistant sensor;
producing a magnetic field with said applied field source, said applied field being of sufficient strength to provide detectable magnetization of a ferromagnetic threat object; and
maintaining sufficient sensor sensitivity to detect the presence of a ferromagnetic threat object while said saturation-resistant sensor is subjected to said applied field.

24. The method recited in claim 23, further comprising biasing said saturation-resistant magnetoresistive sensor with a permanent magnet.

25. The method recited in claim 24, further comprising producing a field of approximately 800 Oe with said biasing permanent magnet.

26. The method recited in claim 23, further comprising concentrating the magnetic flux emanating from a ferromagnetic threat object magnetized by said applied magnetic field, in the vicinity of said saturation-resistant sensor.
